(19) United States
(12) Patent Application Publication
(10) Pub. No.: US 2026/0064008 A1
(43) Pub. Date: Mar. 5, 2026

(54) ADAPTIVE OPTICAL MODULE

(71) Applicant: Carl Zeiss SMT GmbH, Oberkochen (DE)

(72) Inventors: Stefan BAUEREGGER, Dillingen a.d. Donau (DE); Markus RAAB, Schillingsfuerst (DE); Matthias MANGER, Aalen (DE); Axel WITT, Rheinstetten (DE)

(21) Appl. No.: 19/380,564

(22) Filed: Nov. 5, 2025

Related U.S. Application Data
(63) Continuation of application No. PCT/EP2024/062501, filed on May 7, 2024.

(30) Foreign Application Priority Data
May 10, 2023 (DE) 10 2023 204 292.4

(51) Int. Cl. G03F 7/00; G02B 7/185; G02B 26/08

(52) U.S. Cl. CPC G03F 7/70266; G02B 7/185; G02B 26/0825; G03F 7/70308; G03F 7/70525

(57) ABSTRACT

An adaptive optical module has at least one actuator for altering a shape of an optical surface of the optical module. The actuator comprises: a dielectric medium, which is deformable via an electric field, and electrodes for generating the electric field in the dielectric medium by applying an electrical working voltage. The adaptive optical module further comprises a measuring device that measures an impedance present at different values of the working voltage between the electrodes depending on a frequency of an AC voltage applied to the electrodes for measurement purposes, and an evaluation device configured to ascertain from the measured impedance approximately a respective gradient value of characteristic curves each representing a capacitance of the actuator depending on the frequency for the different values of the working voltage and to determine therefrom a deflection of the actuator at at least one operating point of the working voltage.

### CROSS-REFERENCE TO RELATED APPLICATIONS

The present application is a continuation of, and claims benefit under 35 USC 120 to, international application No. PCT/EP2024/062501, filed May 7, 2024, which claims benefit under 35 USC 119 of German Application No. 10 2023 204 292.4, filed May 10, 2023. The entire disclosure of each of these applications is incorporated by reference herein.

### FIELD

The disclosure relates to an adaptive optical module comprising at least one actuator for altering a shape of an optical surface of the optical module, to a microlithographic projection exposure apparatus comprising at least one optical module of this type, and to a method for ascertaining a deflection of an actuator of an adaptive optical module.

### BACKGROUND

A projection lens of a microlithographic projection exposure apparatus with wavefront aberrations that are as small as possible is used to help ensure imaging of the mask structures on the wafer as precisely as possible. Therefore, projection lenses are equipped with manipulators that allow the correction of wavefront errors by changing the state of individual optical elements of the projection lens. Examples of such a change of state comprise a change of pose in one or more of the six rigid-body degrees of freedom of the relevant optical element and a deformation of the optical element.

For the latter change of state, the optical element is usually integrated into an adaptive optical module of the aforementioned type. The latter may comprise one or more piezoelectric or electrostrictive actuators for the purpose of actuating the optical surface. The functionality of such actuators is based on the deformation of a dielectric medium by the application of an electric field. To determine the desired change of state, the aberration characteristic of the projection lens is usually measured regularly and, if appropriate, changes in the aberration characteristic between the individual measurements are determined by simulation. Thus, it is possible to take account of e.g. lens or mirror heating effects by calculation.

When using piezoelectric or electrostrictive adaptive optical elements, issues can be caused by the fact that changes of relevant parameters in the actuator material, for instance on account of temperature variations, aging, defects, drifts, etc., may lead to considerable inaccuracies in the surface shape corrections carried out by the adaptive optical element.

In order to correct or avoid these inaccuracies, DE 10 2020 212 743 A1, for example, proposes the arrangement in the actuator material of a measuring electrode that serves for measuring the temperature and the implementation of corresponding corrections on the basis of the measurement result. This is an indirect measurement and can often lack sufficient accuracy in capturing the surface shape errors caused by actuator deviations.

### SUMMARY

The disclosure seeks to provide an improved adaptive optical module and related apparatuses and methods that, for example, allows a surface shape correction of the adaptive optical element to be implemented with improved accuracy.

In an aspect, the disclosure provides an adaptive optical module which has at least one actuator for altering a shape of an optical surface of the optical module. The actuator comprises a dielectric medium, which is deformable by an electric field, and electrodes for generating the electric field in the dielectric medium by application of an electrical working voltage. Furthermore, the adaptive optical module comprises a measuring device configured to measure an impedance present at different values of the working voltage between the electrodes as a function of a frequency of an AC voltage applied to the electrodes for measurement purposes, and an evaluation device configured to ascertain from the measured impedance approximately a respective gradient value of characteristic curves each representing a capacitance of the actuator as a function of the frequency for the different values of the working voltage and to determine therefrom a deflection of the actuator at at least one operating point of the working voltage.

The adaptive optical module may have a mirror surface or alternatively a lens surface as an optical surface. In the case of a mirror surface, the adaptive optical module can also be referred to as an adaptive mirror module or an adaptive mirror. The deflection of the actuator at the relevant operating point can be understood as meaning the deflection of the actuator in the static or quasi-static state, i.e. the deflection present at a frequency of 0 Hz. The actuator can be embodied as a ferroelectric actuator.

According to the disclosure, it can be possible to determine a deflection of the actuator at at least one operating point on the basis of an electrical measurement at the electrodes. In comparison with an interferometric measurement of the surface shape on the basis of the working voltage, for example, a measurement according to the disclosure at the electrodes can be carried out with a relatively high repetition rate, optionally even during the exposure operation of a microlithographic projection exposure apparatus. The measured impedance can basically be calculated quite easily into the susceptibility χ at the frequency f of the AC voltage taken as a basis for the measurement. The basic susceptibility χₒ or χ_{f0}, i.e. the susceptibility at f=0 Hz or in the static state, can be estimated from the susceptibility χ measured for different frequencies by interpolation. From this, the polarization P in the dielectric medium and, from the latter, the deflection S of the actuator can be determined via the following relationships: P=∫χ_{f0}dE and S˜P², where E denotes the electric field strength in the dielectric medium.

However, the estimation of the basic susceptibility χ_{f0} by interpolation of the measured susceptibilities χ leads to inaccuracies in the estimated basic susceptibility χ_{f0}. These inaccuracies can be avoided by the determination according to the disclosure of the gradient values of the characteristic curves representing the capacitance of the actuator as a function of the frequency. This is because the basic susceptibility χ_{f0} and finally the deflection of the actuator at the relevant operating point of the working voltage can then be determined with a high degree of accuracy from the ascertained gradient values. This then enables a surface shape correction of the adaptive optical element with a likewise high degree of accuracy.

According to one embodiment, the evaluation device is configured to determine a dependence of the deflection of the actuator on the working voltage from the gradient values of the characteristic curves ascertained for the different values of the working voltage. The dependence can be represented by an analytical function of the deflection as a function of the working voltage or by a corresponding conversion table.

According to an embodiment, the evaluation device is configured to determine the dependence of the deflection of the actuator on the working voltage by integrating a characteristic variable ascertained from the gradient value of the characteristic curves over an electric field strength corresponding to the working voltage. The characteristic variable ascertained from the gradient of the characteristic curve is an approximate value for the susceptibility of the actuator in the static state. According to one embodiment variant, the characteristic variable ascertained from the gradient of the characteristic curve differs, for example, only by a factor from the gradient of the characteristic curve. For example, the variable ascertained from the gradient of the characteristic curve may be the susceptibility of the actuator.

According to an embodiment, the characteristic variable determined from the gradient is the susceptibility of the actuator in the static state, i.e. at a frequency of the AC voltage of 0 Hz.

According to an embodiment, the evaluation device is configured to convert the gradient value of the characteristic curves into a gradient value of the susceptibility of the actuator with respect to the frequency in order to ascertain the characteristic variable. The gradient value of the susceptibility with respect to the frequency should be understood as meaning the gradient value of a characteristic curve representing the susceptibility as a function of the frequency. This means that the gradient of the capacitance at a certain frequency is used to calculate the gradient of the susceptibility at the relevant frequency.

According to an embodiment, the evaluation device is configured to carry out the ascertainment of the characteristic curves from the impedance on the basis of an equivalent circuit diagram for the actuator. The equivalent circuit diagram may comprise parallel and/or series connections of ohmic resistors, capacitors and/or inductive elements. According to one embodiment variant, the equivalent circuit diagram comprises a series connection of a capacitor and an ohmic resistor. The capacitance of the capacitor is therefore also referred to as a series capacitance. For example, the equivalent circuit diagram may additionally comprise further series elements and, according to one embodiment variant, also at least one parallel element. These elements may comprise at least one capacitive element, at least one inductive element and/or at least one ohmic resistor. According to an alternative embodiment, the ascertainment of the characteristic curves from the impedance can be carried out on the basis of an equivalent circuit diagram for the actuator which comprises a parallel connection of a capacitor and an ohmic resistor.

According to an embodiment, the evaluation device is configured to ascertain the respective gradient value of the characteristic curves by fitting the relevant characteristic curve. Fitting can be linear or non-linear.

According to an embodiment, the evaluation device is configured to ascertain the respective gradient value of the characteristic curves by a modal analysis of the relevant characteristic curve. Alternatively, the respective gradient value of the characteristic curves can be ascertained using an analytical solution or generally a model-based solution.

According to an embodiment, the adaptive optical module is configured for use in a microlithographic projection exposure apparatus. For example, the projection exposure apparatus may be configured for operation in the EUV wavelength range. According to an alternative embodiment, the optical module is configured for use as a telescope mirror, i.e. as a mirror used in astronomy.

According to an embodiment, the frequencies at which the impedance is measured are in the frequency range between 20 Hz and 200 kHz.

In an aspect, the disclosure provides a microlithographic projection exposure apparatus comprising at least one adaptive optical module according to the disclosure.

According to an embodiment of the projection exposure apparatus, the evaluation device of the adaptive optical module is configured to determine a dependence of the deflection of the actuator on the working voltage from the gradient values ascertained for the different values of the working voltage, wherein the projection exposure apparatus furthermore comprises a control unit configured to ascertain a control value of the working voltage for controlling the actuator from a predefined target deflection of the actuator on the basis of the dependence. In other words, the use of the gradient values ascertained according to the disclosure enables feedforward operation of the adaptive optical module. Alternatively, the ascertained gradient values can also be used to support a control loop.

In an aspect, the disclosure provides a method for ascertaining a deflection of an actuator of an adaptive optical module. The actuator is configured for altering a shape of an optical surface of the optical module and comprises a dielectric medium, which is deformable by an electric field, and electrodes for generating the electric field in the dielectric medium by application of an electrical working voltage. The method comprises the steps of: applying different values of the working voltage and different frequencies of an AC voltage to the electrodes and measuring an impedance present at the respective value of the working voltage as a function of the frequency of the AC voltage, approximately ascertaining a respective gradient value of characteristic curves, each representing a capacitance of the actuator as a function of the frequency, for the different values of the working voltage from the measured impedance and determining a deflection of the actuator at at least one operating point of the working voltage.

According to an embodiment of the method according to the disclosure, the impedance is measured at the respective value of the working voltage for at least two, for example for at least five, for at least ten or for at least twenty, different values of the frequency. According to an embodiment variant, the impedance is measured at the respective value of the working voltage for a maximum of fifteen or a maximum of thirty frequency values.

According to an embodiment, the method according to the disclosure is carried out during an exposure operation of a microlithographic projection exposure apparatus comprising the adaptive optical module. Alternatively, the method according to the disclosure can also be carried out outside the exposure operation, for example during a recovery phase of the projection exposure apparatus.

The features specified with respect to the aforementioned embodiments, exemplary embodiments or embodiment variants, etc., of the adaptive optical module according to the disclosure can be correspondingly applied to the method according to the disclosure, and vice versa. Certain features of the embodiments according to the disclosure will be explained in the description of the figures and in the claims. The individual features may be implemented, either separately or in combination, as embodiments of the disclosure. Furthermore, they may describe various embodiments that are independently protectable and protection for which is claimed only during or after pendency of the application, as the case may be.

### BRIEF DESCRIPTION OF THE DRAWINGS

Certain features of the disclosure will be illustrated in the following detailed description of exemplary embodiments according to the disclosure or of embodiments with reference to the attached schematic drawings, in which:

FIG. 1 shows an embodiment of a microlithographic projection exposure apparatus having an adaptive optical module;

FIG. 2 shows a first embodiment of the adaptive optical element in an initial state and in a corrected state;

FIG. 3 shows a further embodiment of the adaptive optical element in an initial state and in a corrected state;

FIG. 4. shows an embodiment of an actuator of the adaptive optical element according to FIG. 2 with a measuring device for measuring an impedance for different working voltages and an evaluation device for ascertaining gradient values of characteristic curves ascertained from the impedance and determining a dependence of a deflection of the actuator on the working voltage; and

FIG. 5 shows exemplary embodiments of the characteristic curves ascertained by the measuring device according to FIG. 4.

### DETAILED DESCRIPTION

In the exemplary embodiments or embodiments or embodiment variants described below, elements that are functionally or structurally similar to one another are generally provided with the same or similar reference signs as far as reasonably possible. Therefore, for understanding the features of the individual elements of a specific exemplary embodiment, reference should be made to the description of other exemplary embodiments or the general description of the disclosure.

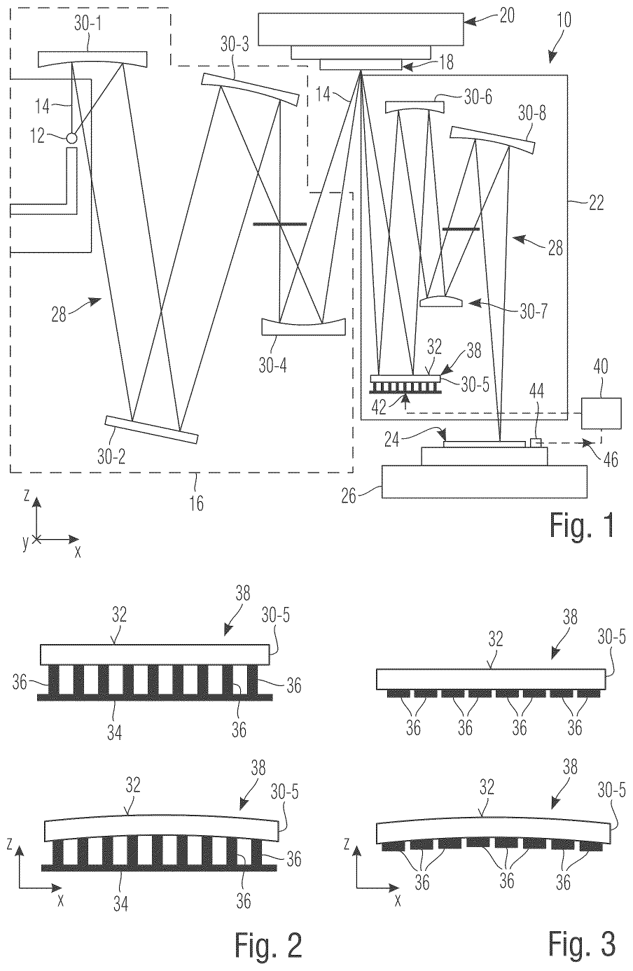

In order to facilitate the description, a Cartesian xyz-coordinate system is indicated in the drawing, from which system the respective positional relationship of the components illustrated in the figures is evident. In FIG. 1, the y-direction runs perpendicularly to the plane of the drawing into the plane, the x-direction runs toward the right, and the z-direction runs upward.

FIG. 1 shows an embodiment according to the disclosure of a microlithographic projection exposure apparatus 10 designed for operation in the EUV wavelength range, i.e. with electromagnetic radiation at a wavelength of shorter than 100 nm, for example a wavelength at approximately 13.5 nm or approximately 6.8 nm. All optical elements are embodied as mirrors as a result of this operating wavelength. However, the disclosure is not restricted to projection exposure apparatuses in the EUV wavelength range. Rather, the disclosure can also be used in other optical systems—for example also in projection exposure apparatuses for UV or DUV wavelengths. For example, further embodiments according to the disclosure may be designed for projection exposure apparatuses with operating wavelengths at approximately 365 nm, 248 nm or 193 nm. In this case, at least some of the optical elements are configured as conventional transmission lens elements.

The projection exposure apparatus 10 according to FIG. 1 comprises an exposure radiation source 12 for creating exposure radiation 14. In the present case, the exposure radiation source 12 is embodied as an EUV source and may for example comprise a plasma radiation source. The exposure radiation 14 initially passes through an illumination optics unit 16 and is directed by the latter onto a mask 18.

The mask 18 comprises mask structures, which are imaged onto a substrate 24 in the form of a wafer during the exposure operation of the projection exposure apparatus 10, and is displaceably mounted on a mask displacement stage 20. The substrate 24 is displaceably mounted on a substrate displacement stage 26. As illustrated in FIG. 1, the mask 18 may be embodied as a reflection mask, or it may also be configured as a transmission mask in an alternative, especially for UV lithography. In the embodiment according to FIG. 1, the exposure radiation 14 is reflected at the mask 18 and thereupon passes through a projection lens 22 that is configured to image the mask structures onto the substrate 24. The substrate 24 is displaceably mounted on a substrate displacement stage 26. The projection exposure apparatus 10 may be embodied as a so-called scanner or a so-called stepper. The exposure radiation 14 is guided within the illumination optics unit 16 and the projection lens 22 via a multiplicity of optical elements, presently in the form of mirrors.

In the embodiment illustrated, the illumination optics unit 16 comprises four optical elements in the form of mirror elements 30-1, 30-2, 30-3 and 30-4. The projection lens 22 also comprises four optical elements in the form of mirror elements 30-5, 30-6, 30-7 and 30-8. The mirror elements 30-1 to 30-8 are arranged in an exposure beam path 28 of the projection exposure apparatus 10 for the purpose of guiding the exposure radiation 14.

In the embodiment shown, the mirror element 30-5 is part of an adaptive optical module 38, which may also be referred to as an adaptive optical element. In the adaptive optical module 30-5, the optical surface of the mirror element 30-5 serves as active optical surface 32 whose shape can be actively modified in order to correct local shape errors. In further embodiments, a different mirror element or a plurality of the mirror elements 30-1, 30-2, 30-3, 30-4, 30-5, 30-6, 30-7 and 30-8 may also each be configured as part of an adaptive optical module.

Furthermore, one or more of the mirror elements 30-1, 30-2, 30-3, 30-4, 30-6, 30-7 and 30-8 or the adaptive optical module 38 of the projection exposure apparatus 10 may be movably mounted. To this end, a respective rigid body manipulator is assigned to each of the movably mounted mirror elements. For example, the rigid body manipulators each enable a tilt and/or a displacement of the assigned mirror elements substantially parallel to the plane in which the respective reflective surface of the optical elements is located. Hence, the position of one or more of the mirror elements may be changed for the purpose of correcting imaging aberrations of the projection exposure apparatus 10.

According to an embodiment, the projection exposure apparatus 10 comprises a control device 40 for creating control signals 42 for the provided manipulation units, such as the aforementioned rigid body manipulators, of one or more adaptive optical modules and/or possibly further manipulators. FIG. 1 illustrates by way of example the transmission of a control signal 42 to the adaptive optical module 38. According to an embodiment for correcting aberrations of the projection lens 22, the control device 40 uses a feedforward control algorithm to ascertain the control signals 42 on the basis of wavefront deviations 46 of the projection lens 22 as measured via a wavefront measuring device 44.

A first embodiment of the adaptive optical module 38 is illustrated in FIG. 2. The illustration in the upper section of FIG. 2 shows the adaptive optical module 38 in an initial state in which the shape of the optical surface 32 has an initial shape, a plane shape in this case. The illustration in the lower section of FIG. 2 shows the adaptive optical module 38 in a corrected state in which the shape of the optical surface 32 has a modified shape, a convexly arched shape in this case.

The adaptive optical module 38 comprises a support element 34 in the form of a back plate and the mirror element 30-5, the top side of which forms the active optical surface 32 and serves to reflect the exposure radiation 14. A multiplicity of actuators 36, which are also referred to as manipulators, are arranged along the underside of the mirror element 30-5. In this case, these can be positioned both in the x-direction and in the y-direction, i.e. in a two-dimensional arrangement, along the underside of the mirror element 30-5. The actuators 36, only a few of which have been provided with a reference sign in FIG. 2 for reasons of clarity, connect the support element 34 to the mirror element 38. The actuators 36 are configured to change their extent along their longitudinal direction in the case of actuation. In the embodiment according to FIG. 2, the actuators 36 are actuatable across or perpendicular to the optical surface 32. The actuators 36 are each driven individually in this case and can therefore be actuated independently of one another.

In the corrected state shown in the lower section of FIG. 2, centrally arranged actuators 36 have an increased length on account of actuation, and so the convexly arched shape arises for the optical surface 32.

FIG. 3 illustrates an embodiment of the adaptive optical module 38. In a manner analogous to FIG. 2, the illustration in the upper section of FIG. 3 shows the adaptive optical module 38 in an initial state in which the shape of the optical surface 32 has a plane shape as the initial shape. The illustration in the lower section of FIG. 3 shows the adaptive optical module 38 in a corrected state in which the shape of the optical surface 32 has a convexly arched and hence a changed shape.

The adaptive optical module 38 according to FIG. 3 differs from the embodiment according to FIG. 2 to the extent that the actuators 36 are arranged on the underside of the mirror element 30-5 not across but parallel to the optical surface 32, and the actuators 36 are not carried by a rigid support element arranged parallel to the mirror element 30-5. That is to say, the actuators 36 are deformable not across the optical surface 32, as in FIG. 2, but parallel to the optical surface 32. As a result of strain or contraction of the individual actuators 36 parallel to the surface, a bending moment is introduced into the mirror element 30-5 and leads to deformation of the latter, as illustrated in the lower section of FIG. 3.

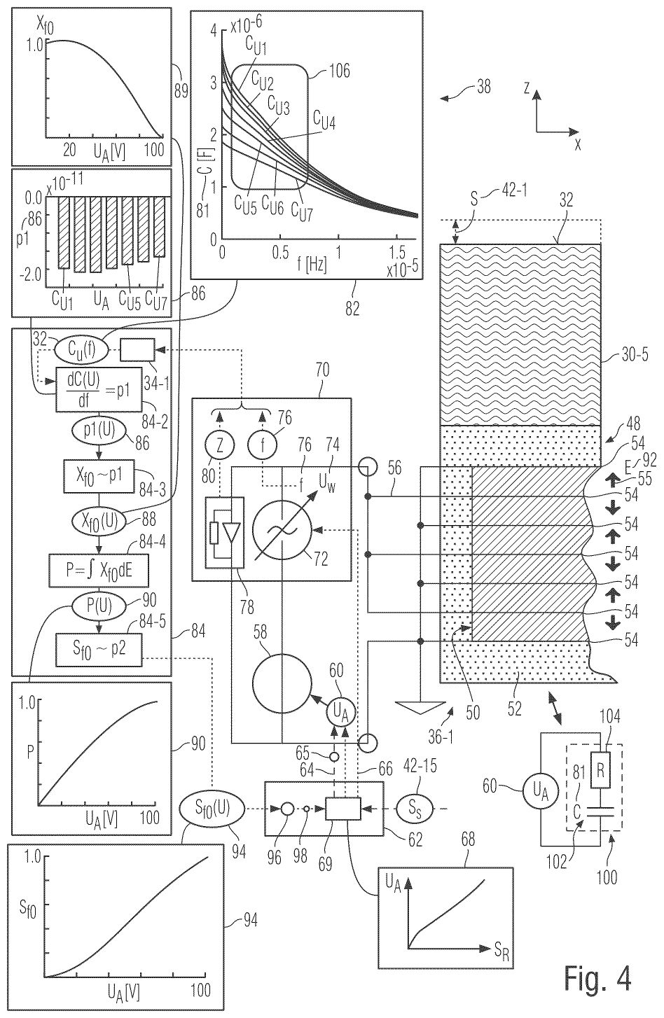

By driving each individual actuator 36, it is possible both in the embodiment according to FIG. 2 and in the embodiment according to FIG. 3 to set profiles of the mirror element 30-5 in a targeted manner and consequently correct the optical system, for example the projection lens 22 or the illumination optics unit 16, of the projection exposure apparatus 10 to the best possible extent. To drive the actuators 36 in this way, the control signal 42 contains target deflections for the various actuators 36. Such a target deflection for one of the actuators 36-1 is indicated in FIG. 4 by the reference sign 42-1S.

FIG. 4 illustrates a section of the adaptive optical element 38 according to FIG. 2 with one of the actuators 36, which is indicated here by the reference sign 36-1. As illustrated by way of example for the actuator 36-1 in FIG. 4, the actuators 36 of the adaptive optical module 38 each comprise a dielectric medium 48 that is deformable by application of an electric field. This may be a piezoelectric material or an electrostrictive material. The deformation is based on the piezoelectric effect in the case of a piezoelectric material, while it is based on the electrostrictive effect in the case of an electrostrictive material. In this text, the electrostrictive effect is understood to mean the component of a deformation of a dielectric medium based on an applied electric field, in which the deformation is independent of the direction of the applied field and, for example, proportional to the square of the electric field. In contrast thereto, the linear response of the deformation to the electric field is referred to as the piezoelectric effect.

In the embodiment variant described below, the actuators 36 are embodied as ferroelectric actuators and are based on the electrostrictive effect. These are particularly well suited to correcting the shape of the active optical surface 32 since these have a very small drift and exhibit only a minor hysteresis.

The actuator 36-1 illustrated in FIG. 4 comprises the dielectric medium 48, which was already mentioned above and which rests against the back side of the mirror element 30-5, electrodes 54, wiring 56 of the electrodes 54, and a voltage generator 58. The dielectric medium 48 has an integral embodiment in the form of a ceramic part, with the electrodes 54 being embedded or integrated therein. The integral dielectric medium 48 is a contiguous and seamless monolithic dielectric medium and is created by sintering, for example.

In other words, the electrodes 54 are arranged in an assemblage with the integral dielectric medium 48. The electrodes 54 are contained in the dielectric medium 48 in the form of an electrode stack. In the embodiment shown, the electrode stack contains seven plate-shaped electrodes 54 arranged one above the other. The entire region of the dielectric medium 48 arranged between electrodes 54 is referred to as the active volume 50 of the dielectric medium 48. The region of the dielectric medium 48 arranged outside the electrode stack is accordingly referred to as the inactive volume 52. In the embodiment shown, the inactive volume 52 completely surrounds the active volume 50.

The wiring 56 of the electrodes 54 connects these in alternating fashion to the positive pole and the negative pole of the voltage generator 58, between which the voltage generator 58 produces a controllable working voltage U_{A} indicated by the reference sign 60. That is to say, the working voltage 60 is a DC voltage with a variable voltage value U_{A}. The wiring 56 is configured in such a way that the electric field 55 created in each case between two adjacent electrodes 50 on account of the applied working voltage 60 alternates with the field strength E (reference sign 92).

Since the dielectric medium 48 is an electrostrictive material in the present case, the expansion of the dielectric medium 48 caused by the electric field 55 is independent of the direction of the electric field 55, i.e. the change in the expansion in the z-direction of the layers of the dielectric medium 48 arranged between the electrodes 54 is directed in the same way. The dielectric medium 48 can be configured as a single crystal or as a polycrystal. At the same time, the dielectric medium contracts in the x-direction and y-direction. Hence, the length expansion of the active volume 50 of the dielectric medium 48 changes in the z-direction when a working voltage 60 generated by the voltage generator 58 is applied, and there is a corresponding change in the x-direction and y-direction. The absolute value of the change in the length expansion depends on the working voltage 60 generated by the voltage generator 58; according to one embodiment, this value is proportional to the value U_{A} of the working voltage 60.

The overall change in the length expansion of the actuator 36-1 when applying a working voltage 60 that differs from 0 V is referred to as deflection S and is provided with reference sign 42-1 in FIG. 4.

Before the adaptive optical module 38 is put into operation, a reference characteristic curve 68 between the deflection S and the working voltage U_{A} is optionally measured in a so-called reference mode. In the reference mode, different values for the working voltage U_{A}, i.e., different operating points of the working voltage U_{A}, are set and the corresponding deflection S_{R} of the optical surface 32 of the actuator 36-1 is measured for each of these values via a reference measuring module in the form of an interferometer.

Furthermore, the embodiment of the adaptive optical element 38 illustrated in FIG. 4 comprises a control unit 62 that is assigned to the depicted manipulator 36-1. This control unit 62 may be part of a control module controlling a plurality of manipulators 36 of the adaptive optical element 38. Furthermore, the control unit may be part of the adaptive optical element 38 or else may be arranged outside the adaptive optical element 38, for example may be part of the control device 40 of the projection exposure apparatus 10.

In a control mode 64, the target deflection Ss (reference sign 42-1s) for the manipulator 36-1 illustrated in FIG. 4, which is contained in the control signal 42 emanating from the control device 40, is read in by the control unit 62. The information flow in the control mode 64 is indicated using dashed lines in FIG. 4. A conversion formula 69 for ascertaining a default for the working voltage U_{A} from the specified target deflection Ss is stored in the control unit 62. For example, the conversion formula 69 can be formed by a curve of the working voltage U_{A} as a function of the target deflection Ss. This curve can be ascertained before the adaptive optical element 30-5 is put into operation from the reference characteristic curve 68 that specifies the curve of S_{R} as a function of U_{A} and is ascertained in the reference mode. Alternatively, the conversion formula may be ascertained via a calibration mode 66 described in more detail below. During operation, the conversion formula 69 is corrected in ongoing fashion, as will be described in more detail below.

For the target deflection Ss that has been read in, the control device 40 ascertains a corresponding control value 65 for the working voltage U_{A} on the basis of the conversion formula 69 and uses this to control the voltage generator 58. A calibration mode 66 for calibrating the conversion formula 69 is applied each time a new working voltage U_{A} is set via the voltage generator 58, or at certain time intervals. The information flow in the calibration mode 66 is shown in FIG. 4 by a dotted line.

To carry out the calibration mode 66, the embodiment of the adaptive optical element 38 illustrated in FIG. 4 comprises a measuring device 70 that is assigned to the depicted actuator 36. The measuring device comprises an AC voltage source 72 which is connected in series with the voltage generator 58 and serves to produce an electrical measuring voltage 74 in the form of an AC voltage U_{W}, on which the working voltage U_{A} is superposed, such that the sum of the working voltage U_{A} and the AC voltage U_{W} is applied in each case between adjacent electrodes 54 of the actuator 36-1. The frequency f (reference sign 76) of the AC voltage U_{W} can be set variably at the AC voltage source 72. The measuring device 70 furthermore comprises an impedance measuring module 78 which is connected to the wiring 56 for the purposes of measuring an impedance Z between the electrodes 54 at the respective frequency f.

During the measurement operation of the measuring device 70, different values for the frequency f are set at the AC voltage source 72, for example the frequency f is tuned continuously or with a fixed increment over a value range. The resultant impedance Z (reference sign 80) is ascertained for each of the set frequency values via the impedance measuring module 78. This is carried out for a multiplicity of working voltages U_{A}.

Furthermore, the embodiment of the adaptive optical element 38 illustrated in FIG. 4 comprises an evaluation device 84 that is assigned to the depicted actuator 36-1. The measured values of the impedance Z ascertained by the impedance measuring module 78 for the various working voltages U_{A} and the respective associated frequency f are transmitted to the evaluation device 84. A first evaluation unit 84-1 of the evaluation device 84 converts the impedance values Z into capacitance values C.

This is carried out on the basis of an equivalent circuit diagram 100 for the actuator 36-1, which in the present case represents a series connection of a capacitor 102 and an ohmic resistor 104. The capacitance of the capacitor 102 can therefore also be referred to as a series capacitance. According to alternative embodiments, the equivalent circuit diagram 100 may additionally comprise further series elements and, according to one embodiment variant, at least one parallel element. According to an embodiment, the equivalent circuit diagram can also represent a parallel connection of a capacitor and an ohmic resistor.

In the present embodiment of the equivalent circuit diagram 100 with the series connection of the capacitor 102 with the capacitance C and the ohmic resistor 104 with the resistance R, the capacitance C (reference sign 81) of the actuator 36-1 can be represented as a function of Z as follows.

$$C = \frac{i}{( Z - R ) \cdot 2 π f} \qquad ( 1 )$$

Here, i represents the imaginary number.

The first evaluation unit 84-1 ascertains the characteristic curves C_{U}(f) indicated by the reference sign 82 by converting the impedance values into the capacitance values C.

These characteristic curves are illustrated by way of example for seven different values U1 to U7 of the working voltage 60 in FIG. 4 in a diagram also indicated by the reference sign 82. The relevant characteristic curves are indicated by C_{U1} to C_{U7} and each show the curve of the capacitance C as a function of the frequency f for the individual working voltages 60.

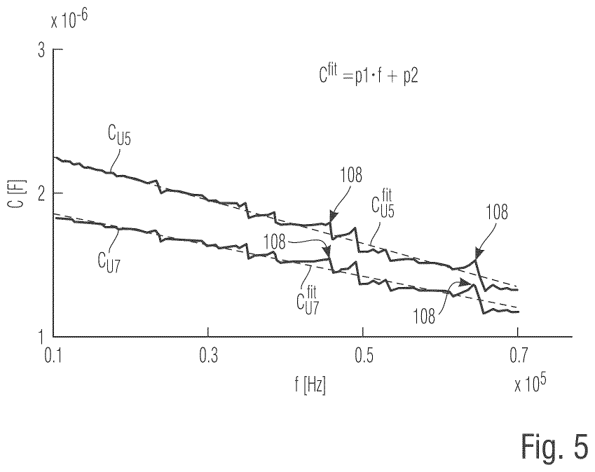

The characteristic curves C_{U1} to C_{U7} are evaluated in an evaluation section 106, in which the characteristic curves approximately have a linear curve. FIG. 5 shows by way of example the curve of the characteristic curves C_{U1} and C_{U7} in the evaluation section 106 in detail resolution. A fit straight line

$${C}_{U 5}^{fit} or {C}_{U 7}^{fit}$$

is depicted using dashed lines for each of the characteristic curves. As can be seen from FIG. 5, the characteristic curves C_{U5} and C_{U7 at} certain frequencies have resonances, some of which are indicated by the reference sign 108.

A second evaluation unit 84-2 of the evaluation device 84 ascertains a respective gradient value p1 for each of the characteristic curves C_{U1} to C_{U7} by linear fitting of the relevant characteristic curve. The underlying fit straight lines are described as follows:

$${C}^{fit} = p 1 \cdot f + p 2 , \qquad ( 2 )$$

that is to say the gradient

$$\frac{dC ( ⋃ )}{df}$$

of the fit straight lines is represented by the parameter p1 which is also referred to as the gradient value 86 of the relevant characteristic curve C_{U1} to C_{U7}.

As can be seen from FIG. 5, the gradient of the fit straight lines

$${C}_{U 5}^{fit}$$

is greater than the gradient of the fit straight lines

$${C}_{U 7}^{fit} ,$$

that is to say p1 is greater for the characteristic curve C_{U5} than for the characteristic curve C_{U7}. This relationship also emerges from the diagram indicated by the reference sign 86 in FIG. 4, in which the p1 values for the different working voltages U_{A} or the different characteristic curves C_{U1} to C_{U7} are shown.

The gradient values p1(U) dependent on the working voltage U_{A}, hereinafter indicated only by U, are transmitted to a third evaluation unit 84-3 of the evaluation device 84. This ascertains therefrom the basic susceptibility indicated by the reference sign 88, i.e. the susceptibility χ_{f0} of the actuator 36-1 in the static state, as a function of the working voltage U. The susceptibility χ_{f0} is also referred to in this text as a characteristic variable ascertained from the gradient value p1 of the characteristic curves C_{U1} to C_{U7}.

To determine the susceptibility χ_{f0}, the evaluation unit 84-3 uses the following relationship:

$$\frac{{ε}_{0}}{2 π} \cdot \frac{d χ}{df} = - {χ}_{0} \cdot {ε}_{0} \cdot const \qquad ( 3 )$$

In this case, ε₀ is the dielectric constant of the dielectric medium. The gradient value

$$\frac{d χ}{df}$$

of the susceptibility of the actuator 36-1 with respect to the frequency can be calculated from

$$\frac{dC}{df} ,$$

i.e. the gradient value 86. The equivalent circuit diagram 100 for the actuator 46-1, which was already used when ascertaining the characteristic curves 82 and comprises a series connection of a capacitor 102 and an ohmic resistor, is taken as a basis for this.

The susceptibility χ_{fo}(U) ascertained by the evaluation unit 84-3 is illustrated by way of example in FIG. 4 in the diagram indicated by the reference sign 88. In this example, the susceptibility χ_{f0} initially rises slightly to 1 with increasing working voltage U_{A} and then drops substantially to the value 0.

A further evaluation unit 84-4 ascertains the polarization P, also indicated by the reference sign 90, in the actuator 36-1 as a function of the working voltage U_{A} by integrating the susceptibility χ_{fo}(U) over the electric field strength E. The electric field strength E can be determined from the working voltage U_{A} applied in each case. The curve of the polarization as a function of the working voltage U_{A} is illustrated in FIG. 4 in the diagram indicated by the reference sign 90.

A further evaluation unit 84-5 ascertains from the polarization P a dependence S_{f0}(U) of the deflection S of the actuator 36-1 on the working voltage U_{A} (in this text also often only indicated by U), which dependence is indicated by the reference sign 94. For this purpose, the polarization P is squared. The dependence S_{f0}(U) is proportional to the square of P:

$${S}_{f 0} \sim {P}^{2} \qquad ( 4 )$$

The curve of the deflection S_{f0}, i.e. the deflection S in the static or quasi-static state as a function of the working voltage U_{A}, indicated by the reference sign 42-1, is illustrated in FIG. 4 in the diagram indicated by the reference sign 94. In other words, the evaluation device 84 is configured to determine the deflection 42-1 of the actuator at different operating points of the working voltage U_{A} from the measured impedance 80.

The functions of the evaluation units 84-1 to 84-5 described above can also be carried out in the evaluation device 84 by fewer evaluation units or only one evaluation unit.

The dependence S_{f0}(U) is transmitted to a comparison module 96 of the control unit 62. The latter compares the characteristic curve specified by the dependence 94 with the reference characteristic curve 68 and brings about a corresponding correction 98 of the conversion formula 69 of the control unit if deviations are found. Alternatively, the control unit calculates the conversion formula 69 directly from the dependence 94. In any case, in the control mode 64, the control unit ascertains the control value 65 of the working voltage U_{A} for the voltage generator 58 on the basis of the determined dependence 94.

According to an embodiment of the evaluation unit 84-2, this ascertains the respective gradient value p1 for each of the characteristic curves C_{U1} to C_{U7} not by linear fitting of the corresponding characteristic curve 82, but by a modal analysis of the relevant characteristic curve 82.

In accordance with one embodiment of the modal analysis, the data relating to the characteristic curves are supported by a model order reduction. This enables particularly stable extraction of the gradient value p1 and thus the deflection 42-1. For this purpose, an optimal basis is extracted from the collected measurement data by singular value decomposition. According to the Eckart-Young theorem, these basic functions are the optimal rank-n basis to be found in terms of the spectral and Frobenius norm. In this case, n denotes the dimension of the underlying data sets or the reduced number of dimensions. In order to support an efficient and stable calculation, the desired rank and error of the model order reduction can be estimated.

According to one embodiment variant of the modal analysis, fewer than five basic functions, for example only the first two basic functions of the modal analysis, are used to determine the gradient values p1 of the characteristic curves 82. According to an embodiment variant of the modal analysis, the extracted basic functions are smoothed using a Gaussian window. This allows the weighting of resonance points to be suppressed. In addition, it is thus possible to mathematically formulate where measurements are intended to be carried out in the frequency.

The condition number of a measurement on the smoothed basic functions, which maps in a stable manner to the unsmoothed basic functions, automatically results in areas in which there are no resonances. This is carried out by forming a matrix C and evaluating the trace of the eigenvalues. According to one embodiment, the characteristic curves 82 evaluated by the modal analysis each comprise 10 to 15 measuring points, i.e. measured values of the capacitance C at 5 to 15 different frequency values f According to further embodiments, the characteristic curves comprise more than 15 measuring points.

The above description of exemplary embodiments, embodiments or embodiment variants should be understood to be by way of example. The disclosure effected thereby firstly enables a person skilled in the art to understand the present disclosure and the features associated therewith, and secondly encompasses alterations and modifications of the described structures and methods that are also obvious in the understanding of a person skilled in the art. Therefore, all such alterations and modifications, insofar as they fall within the scope of the disclosure in accordance with the definition in the accompanying claims, and equivalents are intended to be covered by the protection of the claims.

### LIST OF REFERENCE SIGNS

10 Projection exposure apparatus
12 Exposure radiation source
14 Exposure radiation
16 Illumination optics unit
18 Mask
20 Mask displacement stage
22 Projection lens
24 Substrate
26 Substrate displacement stage
28 Exposure beam path
30-1, 30-2, 30-3, 30-4, 30-5, 30-6, 30-7, 30-8 Mirror elements
32 Active optical surface
34 Support element
36 Actuator
38 Adaptive optical module
40 Control device
42 Control signal
42-1 Deflection of an actuator
42-1S Target deflection of an actuator
44 Wavefront measuring device
46 Wavefront deviations
48 Dielectric medium
50 Active volume
52 Inactive volume
54 Electrodes
55 Electric field
56 Wiring
58 Voltage generator
60 Working voltage
62 Control unit
64 Control mode
65 Control value
66 Calibration mode
68 Reference characteristic curve
69 Conversion formula
70 Measuring device
72 AC voltage source
74 Electrical AC voltage
76 Frequency
78 Impedance measuring module
80 Impedance
81 Capacitance C.
82 Characteristic curves C_{U}(f)
84 Evaluation device
84-1 Evaluation unit
84-2 Evaluation unit
84-3 Evaluation unit
84-4 Evaluation unit
84-5 Evaluation unit
86 Gradient value p1
88 Susceptibility χ_{f0} of the actuator in the static state
90 Polarization
92 Field strength E
94 Dependence S_{f0}(U)
96 Comparison module
98 Correction
100 Equivalent circuit diagram
102 Capacitor
104 Ohmic resistor
106 Evaluation section
108 Resonance

What is claimed is:

1. An adaptive optical module, comprising:
an actuator configured to alter a shape of an optical surface of the optical module, the actuator comprising:
a dielectric medium which is deformable via an electric field; and
electrodes configured to generate the electric field in the dielectric medium by applying an electrical working voltage between the electrodes;
a measuring device configured to measure an impedance present at different values of the electrical working voltage between the electrodes as a function of a frequency of an AC voltage applied to the electrodes; and
an evaluation device configured to:
ascertain from the measured impedance approximately a respective gradient value of characteristic curves, each curve representing a capacitance of the actuator as a function of the frequency of the AC voltage for the different values of the electrical working voltage; and
determine therefrom a deflection of the actuator at at least one operating point of the electrical working voltage.

2. The adaptive optical module of claim 1, wherein the evaluation device is configured to determine a dependence of the deflection of the actuator on the electrical working voltage from the gradient values of the characteristic curves ascertained for the different values of the electrical working voltage.

3. The adaptive optical module of claim 2, wherein the evaluation device is configured to determine the dependence of the deflection of the actuator on the electrical working voltage by integrating a characteristic variable ascertained from the gradient value of the characteristic curves over an electric field strength corresponding to the electrical working voltage.

4. The adaptive optical module of claim 3, wherein the characteristic variable ascertained from the gradient is an approximate value for a susceptibility of the actuator in a static state.

5. The adaptive optical module of claim 3, wherein the evaluation device is configured to convert the gradient value of the characteristic curves into a gradient value of a susceptibility of the actuator with respect to the frequency to ascertain the characteristic variable.

6. The adaptive optical module of claim 5, wherein the evaluation device is configured to ascertain the characteristic curves from the impedance based on an equivalent circuit diagram for the actuator.

7. The adaptive optical module of claim 1, wherein the evaluation device is configured to ascertain the respective gradient value of the characteristic curves by fitting the relevant characteristic curve.

8. The adaptive optical module of claim 1, wherein the evaluation device is configured to ascertain the respective gradient value of the characteristic curves by a modal analysis of the relevant characteristic curve.

9. The adaptive optical module of claim 1, wherein the adaptive optical module is configured for use in a microlithographic projection exposure apparatus.

10. The adaptive optical module of claim 1, wherein the frequencies at which the impedance is measured are between 20 Hz and 200 kHz.

11. The adaptive optical module of claim 1, further comprising an optical element comprising the optical surface.

12. The adaptive optical module of claim 1, further comprising a mirror comprising the optical surface.

13. An apparatus, comprising:
an adaptive optical module according to claim 1,
wherein the apparatus comprises a microlithographic projection exposure apparatus.

14. The apparatus of claim 13, further comprising:
an illumination optics unit; and
a projection lens comprising the adaptive optical module,
wherein:
the illumination optics unit is configured to illuminate an object in an object field of the projection lens; and
the projection lens is configured to image the illuminated object into an image field of the projection lens.

15. The apparatus of claim 13, wherein:
the evaluation device is configured to determine a dependence of the deflection of the actuator on the electrical working voltage from the gradient values ascertained for the different values of the electrical working voltage; and
the apparatus further comprises a control unit configured to ascertain a control value of the electrical working voltage for controlling the actuator from a predefined target deflection of the actuator on the basis of the dependence.

16. The apparatus of claim 13, wherein the adaptive optical module comprises an optical element comprising the optical surface.

17. A method of using a projection exposure apparatus comprising an illumination optics unit and a projection lens, the method comprising:
using the illumination optics unit to illuminate an object in an object field of the projection lens; and
using the projection lens to image the illuminated object into an image field of the projection lens,
wherein the projection lens comprises an adaptive optical module according to claim 1.

18. A method of ascertaining a deflection of an actuator of an adaptive optical module, the actuator being configured to alter a shape of an optical surface of the optical module, the actuator comprising a dielectric medium which is deformable via an electric field, and electrodes configured to generate the electric field in the dielectric medium by applying an electrical working voltage, the method comprising:
applying different values of the electrical working voltage and different frequencies of an AC voltage to the electrodes and measuring an impedance present at each respective value of the electrical working voltage as a function of the frequency of the AC voltage; and
approximately ascertaining a respective gradient value of characteristic curves, each curve representing a capacitance of the actuator as a function of the frequency for the different values of the electrical working voltage from the measured impedance and determining a deflection of the actuator at at least one operating point of the electrical working voltage.

19. The method of claim 18, wherein the impedance is measured at the respective value of the electrical working voltage for at least two different values of the frequency.

20. The method of claim 18, wherein carried out during an exposure operation of a microlithographic projection exposure apparatus comprising the adaptive optical module.
